(19) United States
(12) Patent Application Publication
(10) Pub. No.: US 2025/0033990 A1
(43) Pub. Date: Jan. 30, 2025

(54) METHODS AND APPARATUS FOR STABILIZING VANADIUM COMPOUNDS

(71) Applicant: ASM IP Holding B.V., Almere (NL)

(72) Inventors: Charles Dezelah, Helsinki (FI); Eric James Shero, Phoenix, AZ (US)

(21) Appl. No.: 18/912,849

(22) Filed: Oct. 11, 2024

Related U.S. Application Data
(63) Continuation of application No. 17/238,424, filed on Apr. 23, 2021.
(60) Provisional application No. 63/015,406, filed on Apr. 24, 2020.

(51) Int. Cl. C01G 31/04; C23C 14/06; C23C 14/54; C23C 16/08; C23C 16/455; C23C 16/52; C23C 16/54; C23C 18/16

(52) U.S. Cl. CPC C01G 31/04; C23C 14/0694; C23C 14/548; C23C 16/08; C23C 16/45502; C23C 16/45553; C23C 16/52; C23C 16/54; C23C 18/1619

(57) ABSTRACT

Methods of stabilizing a vanadium compound in a solution, compositions including a vanadium compound and a stabilizing agent, apparatus including the composition, systems that use the composition, and methods of using the compositions, apparatus, and systems are disclosed. Use of the stabilizing agent allows for use of desired precursors, while mitigating unwanted decomposition of the precursors.

### CROSS-REFERENCE TO RELATED APPLICATIONS

This application is a continuation of, and claims priority to, U.S. patent application Ser. No. 17/238,424 filed Apr. 23, 2021 titled METHODS AND APPARATUS FOR STABILIZING VANADIUM COMPOUNDS; which claims priority to U.S. Provisional Patent Application No. 63/015,406 filed Apr. 24, 2020 titled METHODS AND APPARATUS FOR STABILIZING VANADIUM COMPOUNDS, the disclosures of which are hereby incorporated by reference in their entirety.

### FIELD OF INVENTION

The present disclosure generally relates to methods and apparatus suitable for gas-phase reactor systems. More particularly, the disclosure relates to methods, compounds, and apparatus that can be used to stabilize precursors in the gas-phase reactor systems.

### BACKGROUND OF THE DISCLOSURE

Precursors are compounds that can be used to form another material. For example, precursors can be used in gas-phase reactions to form thin films or layers of materials. Unfortunately, some precursors that may have desirable properties, such as desirable vapor pressure at normal pressure and temperature, and/or desired reactivity—e.g., with a surface or another compound—may thermally decompose into other compounds. In particular, some precursors can decompose to produce corrosive gas, which can corrode parts of a reactor system and/or lead to undesired etching during processing. The decomposition can reduce a shelf life of the precursor, complicate manufacturing, require additional purification steps, cause storage and/or shipment problems, and can limit an amount of desired material within a source vessel that is available for reactions within the reactor system. Further, corrosion of reactor system parts can reduce a lifetime of the reactor system and/or parts thereof and consequently increase a cost of operating such equipment. Further, the corrosion can lead to incorporation of reactor system etch products within a deposited film and/or cause etching of a film on a substrate, which, in turn, can lead to a reduction in quality and/or uniformity of such films. Further, because a rate of precursor decomposition generally increases with temperature, an ability to increase flux of the precursor to the reaction chamber by heating the precursor is hampered.

Efforts to reduce decomposition of precursors have resulted in precursors that produce films with undesirably high carbon content, can require an undesirably high temperature to obtain desired flux rates, can result in chemical vapor deposition (CVD) of material when atomic layer deposition (ALD) is desired, can lack desired control of growth rate, and/or can exhibit relatively poor step coverage. Accordingly, improved methods, apparatus and composition for providing precursors for gas-phase reactions are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary introduces a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of stabilizing a vanadium compound in a solution, compositions including a vanadium compound and a stabilizing agent, apparatus including the composition, systems that use the composition, and methods of using the compositions, apparatus, and systems.

In accordance with exemplary embodiments of the disclosure, a method of stabilizing a vanadium compound in a solution is provided. The method can include incorporating an effective amount of one or more stabilizing agents into said solution, wherein the solution includes the vanadium compound and the one or more stabilizing agents. Exemplary vanadium compounds include vanadium halides. The one or more stabilizing agents can comprise an organic molecule. The organic molecule can include one or more of nitrogen, oxygen, sulfur and/or oxygen heteroatom. The one or more stabilizing agents can include an adduct forming compound. Additionally or alternatively, the one or more stabilizing agents can comprise an aprotic compound. Additionally or alternatively, the one or more stabilizing agents can include a compound containing one or more heteroatoms bearing a lone pair of electrons. By way of examples, at least one of the one or more stabilizing agents is selected from the group consisting of a tertiary amine of the formula, NR₃, where all-R groups are independently a C1-C20 alkyl or a C1-C20 aryl group; a tertiary phosphine of the formula, PR₃, where all-R groups are independently a C1-C20 alkyl or a C1-C20 aryl group; an ether of the formula, OR₂, where all-R groups are independently a C1-C20 alkyl or a C1-C20 aryl group; a dialkyl sulfide, diaryl sulfide, or mixed alkyl/aryl sulfide of the formula, SR₂, where all-R groups are independently a C1-C20 alkyl or a C1-C20 aryl group; an aromatic heterocyclic amine, such as pyridine, pyridazine, pyrimidine, pyrazine, or 1,2,4-triazine, and alkyl or aryl substituted versions thereof; an aprotic non-aromatic heterocyclic amine, such as N-alkylpiperidine, N,N′-dialkylpiperazine, N-alkylpyrrolidine, N-alkylpyrrole, N-alkylpyrroline, N,N′-dialkylimidazolidine, and similar compounds, where alkyl can be a C1-C20 hydrocarbon group; an heterocyclic ether, such as furan, tetrahydrofuran, pyran, tetrahydropyran, 1,4-dioxane, 1,4-dioxine, and similar compounds, as well as alkyl or aryl substituted versions thereof; an heterocyclic thioether, such as thiophene, tetrahydrothiophene, thiazole, thiane, thiopyran, dithiane, and similar compounds, as well as common alkyl or aryl substituted versions thereof. The one or more stabilizing agents can be added or present in an amount of 0.001 mol-% to 300 mol-%, or in an amount of 0.1 mol-% to 100 mol-% of the amount of vanadium compound present in the solution.

In accordance with further examples of the disclosure, a composition is provided. Exemplary compositions include a vanadium compound and an effective amount of one or more stabilizing agents—e.g., an amount to mitigate decomposition of the vanadium compound. The vanadium compound can be any vanadium compound, such as a vanadium compound described herein. Similarly, the one or more stabilizing agents can include any suitable stabilizing agent, such as the stabilizing agents describe herein.

In accordance with yet additional embodiments of the disclosure, a vessel for providing a precursor for gas-phase (e.g., semiconductor) processing is provided. The vessel can contain a vanadium compound and/or a composition and/or a solution as described herein. The vessel can include a base and a removable lid.

In accordance with additional examples of the disclosure, an apparatus for manufacturing devices is provided. The apparatus can include a vessel (e.g., a vessel as described herein) that can be attached to a reactor of a reactor system. The vessel can be configured to transport, store, and/or supply to the reactor a composition, such as a composition described herein.

In accordance with further exemplary embodiments of the disclosure, a method for manufacturing a device is provided. The method can include the application of a process comprising: providing a composition to the reactor chamber, the composition comprising a vanadium compound and one or more stabilizing agents. The vanadium compound and/or the one or more stabilizing agents can be as described above and elsewhere herein. The reactor can be a gas-phase reactor designed for manufacturing semiconductor devices. In accordance with examples of the disclosure, the reactor is designed for deposition of thin films. The composition can be a composition as described above and elsewhere herein.

In accordance with additional examples of the disclosure, a system is provided. Exemplary systems can include one or more reaction chambers, a source comprising a composition comprising a vanadium compound and one or more stabilizing agents, and a controller, wherein the controller is configured to control a flow of the composition or the vanadium compound into at least one of the one or more reaction chambers. The composition, vanadium compound, and the one or more stabilizing agents can be as described above and elsewhere herein.

In accordance with yet further examples of the disclosure, a use of one or more stabilizing agents for stabilizing a vanadium compound is provided. The vanadium compound and/or the one or more stabilizing agents can be as described above and elsewhere herein.

In accordance with yet additional examples of the disclosure, a system to perform a method as described herein and/or to form a structure, device, or portion of either, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a reactor system in accordance with additional exemplary embodiments of the disclosure.

FIG. 2 illustrates a vessel and apparatus in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, compositions, vessels, apparatus, systems, and uses thereof provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods, systems, compositions, and apparatus to or to facilitate transporting, storing, and/or suppling a composition and/or a vanadium compound to a (e.g., gas-phase) reactor of a reactor system. Exemplary compositions include one or more stabilizing agents to mitigate unwanted decomposition of the vanadium compound. The methods, compositions, vessels, apparatus, systems, and uses thereof as described herein can be used for a variety of applications, including the applications described in the appendix.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. As used herein, a “vanadium nitride layer” can be a material layer that can be represented by a chemical formula that includes vanadium and nitrogen. A vanadium nitride layer can include additional elements, such as oxygen (e.g., a vanadium oxynitride layer) and the like. As used herein, a “layer comprising vanadium boride” can be a material layer that can be represented by a chemical formula that includes vanadium and boron. In some cases, the layer comprising vanadium boride comprises vanadium diboride (VB2). As used herein, a “layer comprising vanadium phosphide” can be a material layer that can be represented by a chemical formula that includes vanadium and phosphorous. The layer comprising vanadium phosphide can include vanadium (III) phosphide (VP).

As used herein, a “structure” can be or include a substrate as described herein. Structures can include one or more layers overlying the substrate, such as one or more layers formed according to a method as described herein. Devices and device portions can be or include structures or be formed using the structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas (es).

As used herein, a “vanadium compound” includes compounds that can be represented by a chemical formula that includes vanadium.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. Further, whether or not expressly stated, compositions and compounds described herein can comprise, consist essentially of, or consist of compounds and agents noted herein. In this disclosure, any defined meanings do not necessarily exclude ordinary and customary meanings in some embodiments.

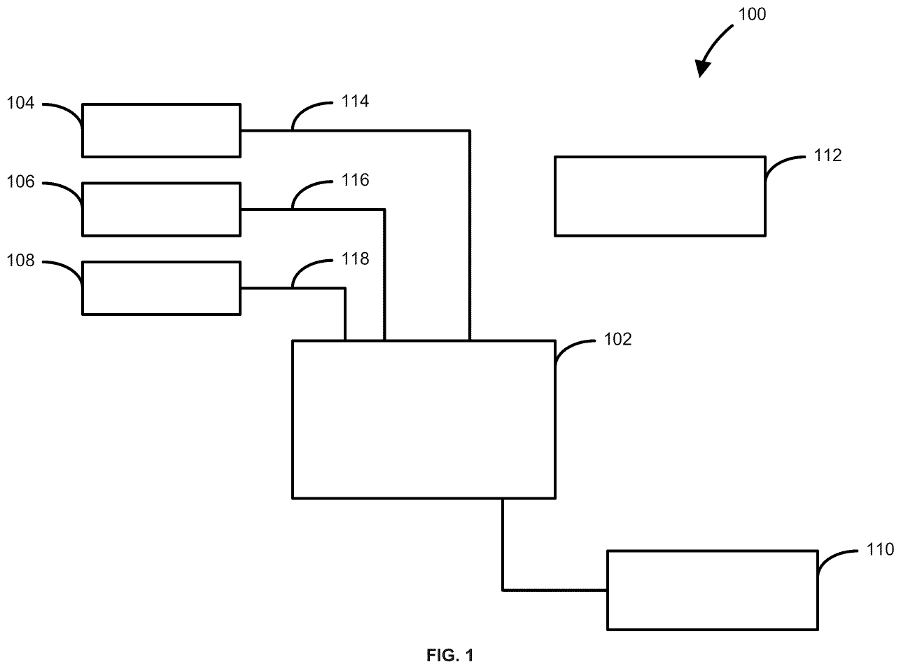

Turning now to the figures, FIG. 1 illustrates a system 100 in accordance with exemplary embodiments of the disclosure. System 100 can be used to perform a method as described herein and/or form a structure or device portion as described herein. Vanadium precursors and compositions described herein may be used to form layers, such as vanadium nitride layers, vanadium boride layers and/or vanadium phosphide layers. A layer comprising one or more of vanadium boride and vanadium phosphide may be used for metal oxide semiconductor (MOS) applications (e.g., as a work function layer and/or dipole or flatband shifter). The vanadium boride and/or vanadium phosphide layers can be used in a variety of applications, including gate stack metal layers, logic or memory (e.g., NAND, V-NAND, DRAM) electrode layer applications, as an etch stop layer (in front (FEOL), middle (MEOL), and/or back (BEOL) end of line processing), and/or as a diffusion barrier layer or liner. By way of particular examples, a vanadium boride and/or vanadium phosphide layer can be used as a work function metal (e.g., for an NMOS device), as a work function adjustment layer, as a voltage threshold adjustment layer, as a (e.g., p) dipole or flatband shifter layer, or the like.

A structure descried herein may be or form part of a CMOS structure, such as one or more of a PMOS and NMOS structure, or other device structure. In some embodiments, the structure may be a gate electrode. Further, structures and devices in accordance with the disclosure can include vertical and/or three-dimensional structures and devices, such as FinFET devices.

In the illustrated example, system 100 includes one or more reaction chambers 102, a precursor gas source 104, a reactant gas source 106, a purge gas source 108, an exhaust source 110, and a controller 112.

Reaction chamber 102 can include any suitable reaction chamber, such as an ALD or CVD reaction chamber.

Precursor gas source 104 can include a vessel and one or more vanadium compounds as described herein, one or more stabilizing agents as described herein, and/or a composition as described herein. As set forth in more detail below, the composition can be a liquid at normal temperature and pressure.

Reactant gas source 106 can include a vessel and one or more reactants (e.g., boron reactant, phosphorus reactant, nitrogen reactant, carbon reactant, sulfur reactant)—alone or mixed with another compound. Purge gas source 108 can include one or more inert gases as described herein. Although illustrated with three gas sources 104-108, system 100 can include any suitable number of gas sources. Gas sources 104-108 can be coupled to reaction chamber 102 via lines 114-118, which can each include flow controllers, valves, heaters, and the like.

Exhaust source 110 can include one or more vacuum pumps.

Controller 112 includes electronic circuitry and software to selectively operate valves, manifolds, heaters, pumps and other components included in the system 100. Such circuitry and components operate to introduce precursors, reactants, and purge gases from the respective sources 104-108. By way of examples, controller 112 can be configured to control a flow of the composition or the vanadium compound into at least one of the one or more reaction chambers. Controller 112 can control timing of gas pulse sequences, temperature of the substrate and/or reaction chamber, pressure within the reaction chamber, and various other operations to provide proper operation of the system 100. Controller 112 can include control software to electrically or pneumatically control valves to control flow of precursors, reactants and purge gases into and out of the reaction chamber 102. Controller 112 can include modules such as a software or hardware component, e.g., a FPGA or ASIC, which performs certain tasks. A module can advantageously be configured to reside on the addressable storage medium of the control system and be configured to execute one or more processes.

Other configurations of system 100 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 102. Further, as a schematic representation of a system, many components have been omitted for simplicity of illustration, and such components may include, for example, various valves, manifolds, purifiers, heaters, containers, vents, and/or bypasses.

During operation of reactor system 100, substrates, such as semiconductor wafers (not illustrated), are transferred from, e.g., a substrate handling system to reaction chamber 102. Once substrate(s) are transferred to reaction chamber 102, one or more gases from gas sources 104-108, such as precursors, reactants, carrier gases, and/or purge gases, are introduced into reaction chamber 102.

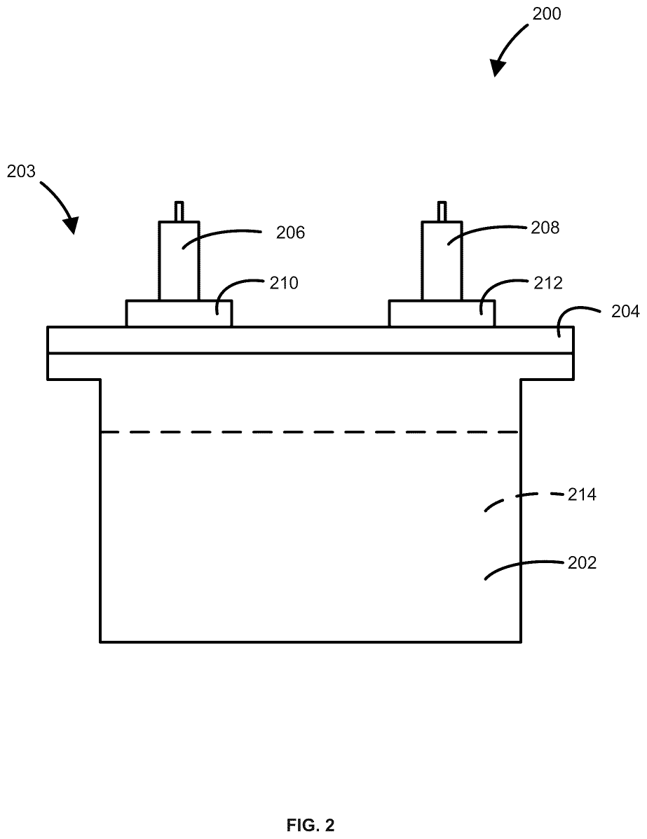

FIG. 2 illustrates an apparatus 200. Apparatus 200 can be attached to a reactor of a reactor system. For example, apparatus 200 can be used as or form part of, for example, gas source 104.

In the illustrated example, apparatus 200 comprises vessel 203 comprising a base 202 and a lid 204 for containing a composition 214 within vessel 203. Vessel 203 can be configured to transport, store, and/or supply to the reactor composition 214.

Vessel 203 can be formed of any suitable material. By way of examples, base 202 and/or lid 204 of vessel 203 can be formed of stainless steel. In other embodiments, base 202 and/or lid 204 can be formed of high nickel alloys, aluminum, or titanium. It should be understood that base 202 and/or lid 204 can be formed of any other material that is inert or not react with composition 214 within the vessel 203 to any appreciable extent.

Lid 204 can be removably attached to base 202. When lid 204 is removably attached to base 202, a seal (not illustrated) can be disposed between lid 204 and base 202 to ensure the contents within vessel 203 are secured there within. In an embodiment, base 202 and lid 204 are formed of the same material, such that both have substantially the same thermal conductivity and the same coefficient of thermal expansion. In another embodiment, base 202 can be formed of a material different than the material used to form lid 204.

Apparatus 200 can also include one or more valves 206, 208 coupled to lid 204 and in fluid communication with an interior of base 202. Apparatus 200 can optionally include one or more blocks 210, 212 that can include an internal gas flow passage.

Compositions suitable for use as composition 214 can include a vanadium compound and an effective amount of one or more stabilizing agents. Compositions can sometimes be referred to herein as solutions. The stabilizing agents can or can facilitate a reduction of unwanted thermal decomposition of the vanadium compound, such as decomposition that might otherwise occur during transport or storage of the vanadium compound. By way of examples, the stabilizing agent can bond and/or form adducts with the vanadium compound and/or include a solvent that stabilizes the vanadium compound. Existing solutions for stabilizing compounds such as vanadium tetrachloride (VCl⁴) include use of strong chlorinating agents to disfavor decomposition. However, strong chlorinating agents, such as acetyl chloride or phosphorus trichloride, are corrosive and use of such compounds may yield environmental, health, and/or safety concerns and/or may cause impurities to be deposited in layers formed using the compositions.

The vanadium precursor can include, for example, one or more of a vanadium halide, a vanadium oxyhalide, a vanadium organometallic compound, a vanadium metal organic compound, a vanadium beta-diketonate compound, a vanadium cyclopentadienyl compound, a vanadium alkoxide compound, a vanadium dialkylamido compound, a vanadium amidinate compound, a DAD ligand compound, where DAD is represented by 1,4-diaza-1,3-butadiene (RN═CR′CR′═NR, R═alkyl, aryl, R′═H, alkyl), and a vanadium heteroleptic or mixed ligand compound, or the like.

By way of particular examples, a vanadium halide can be selected from one or more of a vanadium fluoride, a vanadium chloride, a vanadium bromide, and a vanadium iodide. The vanadium halide can include only vanadium and one or more halogens—e.g., vanadium tetrachloride or the like. A vanadium oxyhalide can be selected from one or more vanadium oxyhalides, such as one or more of a vanadium oxyfluoride, a vanadium oxychloride, a vanadium oxybromide, and a vanadium oxyiodide. The vanadium oxyhalide can include only vanadium, oxygen, and one or more halides. By way of examples, the vanadium halide and oxyhalide can be selected from the group consisting of and include one or more of VCl₄, VBr₄, VI₄, VOCl₄, VOBr₃, and VOI₃ (respectively named as vanadium tetrachloride, vanadium tetrabromide, vanadium tetraiodide, vanadiumoxytrichloride, vanadiumoxytribromide, and vanadiumoxytriiodide).

Exemplary vanadium beta-diketonate compounds include VO(acac)₂, VO(thd)₂, V(acac)₃, V(thd)₃ (respectively named as oxobis(2,4-pentanedionato) vanadium (IV), oxobis(2,2,6,6-tetramethyl-3,5-hepanedionato) vanadium (IV), tris(2,4-pentanedionato) vanadium (IV), and tris(2,2,6,6-tetramethyl-3,5-hepanedionato) vanadium (IV)), and/or VO(hfac)₂ or V(hfac)₃, where hfac is a hexaflouroacetylacetonato ligand, and the like.

Exemplary vanadium cyclopentadienyl compounds include VCp₂Cl₂, VCp₂, VCp₂(CO)₄, and VCpCl₃, (respectively named as bischlorobis(cyclopentdienyl) vanadium (IV), bis(cyclopentadienyl) vanadium (II), cyclopentadienylvanadium tetracarbonyl, and trichloro(cyclopentadienyl) vanadium (IV)). Additional exemplary vanadium cyclopentadienyl compounds include variations of these compounds, where Cp is either unsubstituted or bearing one or more alkyl groups, e.g., MeCp, EtCp, iPrCp, and the like.

Exemplary vanadium alkoxide compounds include V(OMe)₄, V(OEt)₄, V(OiPr)₄, V(OtBu)₄, VO(OMe)₃, VO(OEt)₃, VO(OiPr)₃, and VO(OtBu)₃, (respectively named as tetrakis(methoxy) vanadium (IV), tetrakis(ethoxy) vanadium (IV), tetrakis(isopropoxy) vanadium (IV), tetrakis(t-butoxy) vanadium (IV), oxotris(methoxy) vanadium (IV), oxotris(ethoxy) vanadium (IV), oxotris(isopropoxy) vanadium (IV), and oxotris(t-butoxy) vanadium (IV)). Additional vanadium alkoxide compounds include variations of these compounds, where other alkoxy ligands are used.

Exemplary vanadium dialkylamido compounds include V(NMe₂)₄, V(NEt₂)₄, and V(NEtMe)₄, as (respectively named tetrakis(dimethylamido)vanadium (IV), tetrakis(diethylamido)vanadium(IV), and tetrakis(ethylmethylamido)vanadium(IV)).

Exemplary amidinate compounds include V(iPrFMD)₃, V(iPrAMD)₃, V(tBuFMD)₃, and V(tBuAMD)₃, where iPrFMD is an N,N′-diisopropylformamidinato ligand, iPrAMD is an N,N′-diisopropylacetamidinato ligand, tBuFMD is an N,N′-di-tert-butylformamidinato ligand, and tBuAMD is an N,N′-di-tert-butylacetamidinato ligand.

Examples of precursors including a DAD ligand include V(DAD)₂, V(DAD)(CO)₄, VCp(DAD)(CO)₂, V(DAD)Cl₃, and V(DAD)₂(NO)₂, where DAD is 1,4-diaza-1,3-butadiene (RN═CR′CR′═NR, where R=alkyl or an aryl group, and R′═H, or an alkyl group).

Further, exemplary vanadium precursors can include “heteroleptic” or mixed ligand precursors, where any combination of the exemplary ligand types in any attainable number (typically 3-5 ligands, but there can be exceptions) can be attached to the vanadium atom. Examples could include V(Cl)ₓ(NMe)₄₋ₓ and V(Cl)ₓ(iPrAMD)ₓ.

Use of vanadium halide precursors can be advantageous relative to methods that use other precursors, such as vanadium metalorganic precursors, because the vanadium halide precursors can be relatively inexpensive, can result in vanadium layers with lower concentrations of impurities, such as carbon, and/or processes that use such precursors can be more controllable-compared to processes that use metalorganic or other vanadium precursors. Further, such reactants can be used without the assistance of a plasma to form excited species. In addition, processes that use vanadium halide may be easier to scale up, compared to methods that use organometallic vanadium precursors.

In accordance with examples of the disclosure, the composition is a liquid at normal temperature and pressure.

In accordance with examples of the disclosure, the vanadium compound comprises a vanadium halide. The vanadium halide can be or include a vanadium chloride, such as vanadium tetrachloride.

Exemplary stabilizing agents can include an adduct forming compound. Additionally or alternatively, one or more of the stabilizing agents comprise a compound having one or more of the following properties: 1) aprotic (e.g., is an aprotic compound), lacking hydrogens that are capable of being protonized by the vanadium compound, 2) containing one or more heteroatoms bearing a lone pair of electrons capable of forming a dative bond to vanadium to form an adduct, 3) selected in such a way as to not impact the delivery of the vanadium compound vapor or vanadium compound adduct vapor, 4) selected in such a way as to minimize incorporation of the stabilizer into the vanadium-containing film as an impurity, and/or 5) introduced in a quantity ranging from trace “catalytic inhibitor” amounts, up to 1:1 stoichiometric quantities. The desired ratio can depend, for example, on the particular vanadium compound and desired stabilization.

In accordance with embodiments of the disclosure, at least one of the one or more stabilizing agents can be or include an organic molecule. The organic molecule can include one or more of nitrogen, oxygen, sulfur and/or oxygen heteroatom.

In accordance with further examples of the disclosure, at least one of the one or more stabilizing agents can be selected from the group consisting of a tertiary amine of the formula, NR₃, where all-R groups are independently a C1-C20 alkyl or a C1-C20 aryl group; a tertiary phosphine of the formula, PR₃, where all-R groups are independently a C1-C20 alkyl or a C1-C20 aryl group; an ether of the formula, OR₂, where all-R groups are independently a C1-C20 alkyl or a C1-C20 aryl group; a dialkyl sulfide, diaryl sulfide, or mixed alkyl/aryl sulfide of the formula, SR₂, where all-R groups are independently a C1-C20 alkyl or a C1-C20 aryl group; an aromatic heterocyclic amine, such as pyridine, pyridazine, pyrimidine, pyrazine, or 1,2,4-triazine, and alkyl or aryl substituted versions thereof; an aprotic non-aromatic heterocyclic amine, such as N-alkylpiperidine, N,N′-dialkylpiperazine, N-alkylpyrrolidine, N-alkylpyrrole, N-alkylpyrroline, N,N′-dialkylimidazolidine, and similar compounds, where alkyl can be a C1-C20 hydrocarbon group; an heterocyclic ether, such as furan, tetrahydrofuran, pyran, tetrahydropyran, 1,4-dioxane, 1,4-dioxine, and similar compounds, as well as alkyl or aryl substituted versions thereof; an heterocyclic thioether, such as thiophene, tetrahydrothiophene, thiazole, thiane, thiopyran, dithiane, and similar compounds, as well as common alkyl or aryl substituted versions thereof, or the like. The solution or composition can include any suitable number of stabilizing agents, such as two or more stabilizing agents, wherein one or more of the two or more stabilizing agents can be selected from the list above. The two or the two or more stabilizing agents can include any combination of two or more stabilizing agents, including at least one stabilizing agent from the examples provided above,

In accordance with further examples of the disclosure, a method of stabilizing a vanadium compound in a solution (also referred to herein as composition) is provided. The method can include incorporating an effective amount of one or more stabilizing agents into the solution. By way of examples, the one or more stabilizing agents can be added in an amount of 0.001 mol-% to 300 mol-% or in an amount of 0.1 mol-% to 100 mol-% of the amount of vanadium compound present in the solution. Thus, the one or more stabilizing agents may be added in an amount of 1 mol-%, 25 mol-%, 50 mol-% or 200 mol-% of vanadium compound present in the solution. The proportions of vanadium compound and one or more stabilizing agents present in the solution may be calculated according to the amounts present in the solution when the solution is prepared.

In accordance with additional embodiments of the disclosure, a method for manufacturing a device is provided. The method can include the application of a process comprising: providing a composition, such as a composition or solution described herein, to the reactor chamber. In accordance with examples of the disclosure, the reactor is designed for manufacturing semiconductor devices. In accordance with further examples of the disclosure, the reactor is designed for deposition of thin films or layers, such as one or more layers comprising vanadium. Exemplary vanadium layers are set forth in the appendix, which forms part of this disclosure.

In accordance with yet additional embodiments of the disclosure, a use of one or more stabilizing agents for stabilizing a vanadium compound is provided. The stabilizing agents can include at least one, and in some cases, can include at least two of the stabilizing agents noted herein. The vanadium compound can include, for example, a vanadium compound as noted herein.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of stabilizing a vanadium compound in a solution, the method comprising incorporating an effective amount of one or more stabilizing agents into said solution, wherein the one or more stabilizing agents comprise one or more of an organic molecule comprising a sulfur heteroatom, an ether of the formula O[R¹]₂, a tertiary amine of the formula N[R²]₃, pyran, tetrahydropyran, pyridazine, pyrimidine, pyrazine, 1,2,4-triazine, and an aprotic non-aromatic heterocyclic amine,
wherein all R¹ groups are independently a C1-C20 alkyl or a C1-C20 aryl group, and wherein where all R² groups are independently a C1-C20 aryl group.

2. The method according to claim 1, wherein the vanadium compound comprises a vanadium halide.

3. The method according to claim 1, wherein the one or more stabilizing agents comprise an organic molecule comprising a sulfur heteroatom.

4. The method according to claim 3, wherein the one or more stabilizing agents comprise a dialkyl sulfide, diaryl sulfide, or mixed alkyl/aryl sulfide of the formula, S[R³]₂, where all —R³ groups are independently a C1-C20 alkyl or a C1-C20 aryl group.

5. The method according to claim 3, wherein the one or more stabilizing agents comprise a heterocyclic thioether, such as thiophene, tetrahydrothiophene, thiazole, thiane, thiopyran, dithiane, and similar compounds, as well as common alkyl or aryl substituted versions thereof.

6. The method according to claim 1, wherein the one or more stabilizing agents comprise an ether of the formula, O[R¹]₂, where all —R¹ groups are independently a C1-C20 alkyl or a C1-C20 aryl group.

7. The method according to claim 1, wherein the one or more stabilizing agents comprise one or more of pyran, tetrahydropyran, pyridazine, pyrimidine, pyrazine, and 1,2,4-triazine.

8. The method according to claim 1, wherein the one or more stabilizing agent is added in an amount of 0.001 mol-% to 300 mol-% or in an amount of 0.1 mol-% to 100 mol-% of the amount of vanadium compound present in the solution.

9. The method according to claim 1, wherein the one or more stabilizing agents comprise a tertiary amine of the formula, N[R²]₃, where all —R² groups are independently a C1-C20 aryl group.

10. The method according to claim 1, wherein the one or more stabilizing agents comprise two or more stabilizing agents.

11. A composition comprising a vanadium compound and an effective amount of one or more stabilizing agents, wherein the one or more stabilizing agents comprise one or more of an organic molecule comprising a sulfur heteroatom, an ether of the formula O[R¹]₂, a tertiary amine of the formula N[R²]₃, pyran, tetrahydropyran, pyridazine, pyrimidine, pyrazine, 1,2,4-triazine, and an aprotic non-aromatic heterocyclic amine,
wherein all R¹ groups are independently a C1-C20 alkyl or a C1-C20 aryl group, and wherein where all R² groups are independently a C1-C20 aryl group.

12. The composition according to claim 11, wherein the vanadium compound comprises a vanadium halide.

13. The composition according to claim 11, wherein the composition is a liquid at normal temperature and pressure.

14. The composition according to claim 11, wherein the one or more stabilizing agents comprise two or more stabilizing agents.

15. A vessel for providing a precursor for gas-phase processing, wherein the vessel contains a vanadium compound and one or more stabilizing agents, wherein the one or more stabilizing agents comprise one or more of an organic molecule comprising a sulfur heteroatom, an ether of the formula O[R¹]₂, a tertiary amine of the formula N[R²]₃, pyran, tetrahydropyran, pyridazine, pyrimidine, pyrazine, 1,2,4-triazine, and an aprotic non-aromatic heterocyclic amine,
wherein all R¹ groups are independently a C1-C20 alkyl or a C1-C20 aryl group, and wherein where all R² groups are independently a C1-C20 aryl group.

16. The vessel according to claim 15, wherein the vanadium compound comprises a vanadium halide.

17. The vessel according to claim 15, wherein the one or more stabilizing agents comprise two or more stabilizing agents.

18. The vessel according to claim 15, wherein the one or more stabilizing agents comprise an organic molecule comprising a sulfur heteroatom.

19. A system comprising:
one or more reaction chambers;
a source comprising a composition comprising a vanadium compound and one or more stabilizing agents; and
a controller,
wherein the controller is configured to control a flow of the composition or the vanadium compound into at least one of the one or more reaction chambers, and
wherein the one or more stabilizing agents comprise one or more of an organic molecule comprising a sulfur heteroatom, an ether of the formula O[R¹]₂, a tertiary amine of the formula N[R²]₃, pyran, tetrahydropyran, pyridazine, pyrimidine, pyrazine, 1,2,4-triazine, and an aprotic non-aromatic heterocyclic amine,
wherein all R¹ groups are independently a C1-C20 alkyl or a C1-C20 aryl group, and wherein where all R² groups are independently a C1-C20 aryl group.

20. The system according to claim 19, wherein the vanadium compound comprises a vanadium halide.
